(19) United States
(12) Patent Application Publication
(10) Pub. No.: US 2025/0284197 A1
(43) Pub. Date: Sep. 11, 2025

(54) RESIST TOPCOAT COMPOSITION, AND METHOD OF FORMING PATTERNS USING THE COMPOSITION

(71) Applicant: SAMSUNG SDI CO., LTD., Yongin-si (KR)

(72) Inventors: Ran NAMGUNG, Suwon-si (KR); Kyoungjin HA, Suwon-si (KR); Hyeon PARK, Suwon-si (KR); Daeseok SONG, Suwon-si (KR)

(21) Appl. No.: 19/024,983

(22) Filed: Jan. 16, 2025

(30) Foreign Application Priority Data
Mar. 11, 2024 (KR) 10-2024-0034115

(51) Int. Cl. G03F 7/11; G03F 7/16; G03F 7/20; G03F 7/32

(52) U.S. Cl. CPC G03F 7/11; G03F 7/168; G03F 7/2004; G03F 7/322

(57) ABSTRACT

A resist topcoat composition and a method of forming patterns using the resist topcoat composition are provided. The resist topcoat composition may include a copolymer including a first structural unit represented by Chemical Formula M-1 and a second structural unit represented by Chemical Formula M-2, an amide-based matting agent, and a solvent.

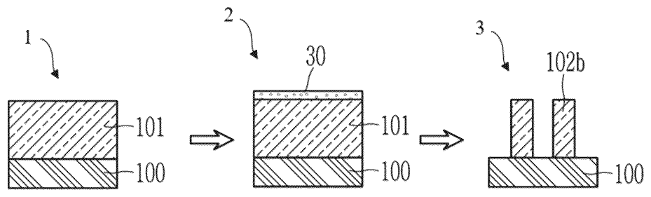

### CROSS-REFERENCE TO RELATED APPLICATION

This application claims priority to and the benefit of Korean Patent Application No. 10-2024-0034115, filed on Mar. 11, 2024, in the Korean Intellectual Property Office, the entire content of which is incorporated herein by reference.

### BACKGROUND

### 1. Field

This disclosure relates to a resist topcoat composition and a method of forming patterns using the same.

### 2. Description of the Related Art

Recently, the semiconductor industry has developed the utilization (advanced the application) of ultrafine techniques characterized by patterns that span a mere few nanometers to several tens of nanometers (i.e., having a pattern with dimensions of a few nanometer, to several tens of nanometers in size). The deployment of such precise methodologies necessitates the adoption of sophisticated photolithographic processes, which are integral to achieving the desired dimensional accuracy (i.e., the implementation of a suitable ultrafine technique essentially requires (or there is a desire for) effective photolithographic processes capable of producing the proper dimensions).

Comparable photolithographic processes include forming a material layer on a semiconductor substrate, coating a photoresist layer thereon, exposing and developing to form a photoresist pattern, and then etching the material layer using the photoresist pattern as a mask.

As photolithography processing techniques develop, there is a notable enhancement in pattern integration (i.e., a degree of pattern integration is increasing), and materials and technologies for solving the numerous challenges that arise (i.e., presented by the requirements (e.g., desires) of these processes) are continuously needed, desired, or required.

In particular, when extreme ultraviolet (EUV) wavelength light is irradiated onto (e.g., to) the photoresist, there may be a region where more than (or less than) the intended quantity of light is randomly irradiated in one or more regions. The random irradiation may occur due to an excessive (e.g., large) amount of energy per photon, which is termed a “photo shot noise,” or may occur due to an EUV absorption difference between the top and bottom (e.g., upper and lower portions) of the photoresist, which may cause pattern distribution deterioration. For example, a photo shot noise or pattern distribution deterioration may result in pattern roughness (e.g., LER: line edge roughness, LWR: line width roughness) or IPU (in-point uniformity), and/or the like. Accordingly, successful implementation of photolithographic processes to enhance or improve pattern distribution deterioration requires (or there is a desire for) the development of improved resist topcoat composition technology.

### SUMMARY

One or more aspects of embodiments of the present disclosure are directed toward a resist topcoat composition capable of preventing or reducing pattern distribution by preventing or reducing pattern deterioration.

One or more aspects of embodiments of the present disclosure are directed toward a method of forming patterns using the resist topcoat composition.

Additional aspects will be set forth in part in the description which follows and, in part, will be apparent from the description, or may be learned by practice of the presented embodiments of the disclosure.

Some embodiments of the present disclosure provide a resist topcoat composition including a copolymer including a first structural unit represented by Chemical Formula M-1 and a second structural unit represented by Chemical Formula M-2, an amide-based matting agent, and a solvent.

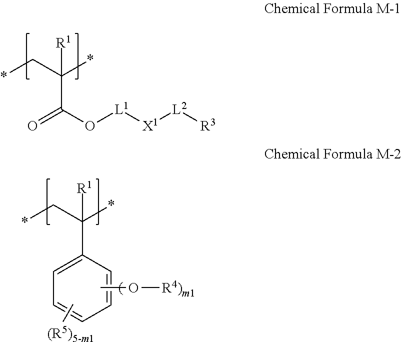

In Chemical Formula M-1 and Chemical Formula M-2,
R¹ and R² may each independently be hydrogen or a substituted or unsubstituted C1 to C10 alkyl group,
L¹ and L² may each independently be a single bond, a substituted or unsubstituted C1 to C10 alkylene group, and/or a (e.g., any suitable) combination thereof,
X¹ may be a single bond, —O—, —S—, —S(O)—, —S(O)₂—, —C(O)—, —(CO)O—, —O(CO), —O(CO)O—, —NR^{a}— (wherein, R^{a} is hydrogen, deuterium, or a substituted or unsubstituted C1 to C10 alkyl group), and/or a (e.g., any suitable) combination thereof,
R³ may be hydrogen, fluorine, a hydroxyl group, a substituted or unsubstituted C1 to C20 alkyl group, and/or a (e.g., any suitable) combination thereof,
R⁴ may be hydrogen, or C(═O)R^{b},
R^{b} may be a substituted or unsubstituted C1 to C10 alkyl group, at least one selected from among R³, L¹, and L² may include fluorine and a hydroxyl group,
R⁵ may be hydrogen, a halogen, a hydroxyl group, a substituted or unsubstituted C1 to C10 alkyl group, and/or a (e.g., any suitable) combination thereof,
m1 may be any one of the integers from 1 to 4, and

* is a linking point.

Some embodiments provide a method of forming patterns (e.g., resist patterns) which includes coating and heating a photoresist composition on a substrate to form a (e.g., at least one) photoresist layer, coating and heating the aforementioned resist topcoat composition on the photoresist layer to form a (e.g., at least one) topcoat, and exposing and developing the topcoat and the photoresist layer to form a pattern (e.g., patterns (e.g., resist patterns)).

The resist topcoat composition according to one or more embodiments may remove excess activated acid from the upper portion of the photoresist if (e.g., when) exposed to EUV, to improve distribution by preventing or reducing deterioration of pattern roughness (LER, LWR) or IPU due to the difference in EUV absorption between the upper and lower portions of the photoresist, and to greatly improve the IPU of the pillar pattern, which can be used effectively for forming patterns (e.g., fine patterns) in photoresist.

### BRIEF DESCRIPTION OF THE DRAWING

The accompanying drawing is included to provide a further understanding of the present disclosure, and is incorporated in and constitutes a part of this specification. The drawing is a schematic view for explaining a method of forming patterns using a resist topcoat composition according to one or more embodiments. The drawing illustrates an example embodiment, and together with the detailed description, facilitates explanation of the principles of the present disclosure.

### DETAILED DESCRIPTION

Hereinafter, example embodiments of the present disclosure will be described in more detail so that those skilled in the art can easily implement them. However, this disclosure may be embodied in many different forms and is not construed as limited to the example embodiments set forth herein, rather the present disclosure is defined by the scope of claims. In this regard, the present embodiments may have different forms and should not be construed as being limited to the descriptions set forth herein. Thus it should be appreciated that all changes, equivalents, and substitutes that do not depart from the spirit and technical scope are encompassed in the present disclosure.

In the drawing, the thickness of layers, films, panels, regions, and/or the like, are exaggerated for clarity and like reference numerals designate like elements throughout the specification, and duplicative descriptions thereof may not be provided. It will be understood that if (e.g., when) an element such as a layer, film, region, or substrate is referred to as being “on” another element, it can be directly on the other element or intervening elements may also be present. In contrast, if (e.g., when) an element is referred to as being “directly on” another element, there are no intervening elements present.

Unless otherwise defined, all chemical names, technical and scientific terms, and terms defined in common dictionaries should be interpreted as having meanings consistent with the context of the related art, and should not be interpreted in an ideal or overly formal sense. It will be understood that, although the terms first, second, and/or the like may be used herein to describe certain elements, these elements should not be limited by these terms. These terms are only used to distinguish one element from another element. Thus, a first element could be termed a second element without departing from the teachings of the present disclosure. Similarly, a second element could be termed a first element.

As used herein, expressions such as “at least one of,” “one of,” “at least one selected from among,” and “selected from among,” if (e.g., when) preceding a list of elements, modify the entire list of elements and do not modify the individual elements of the list. As utilized herein, the expressions “at least one of A, B, or C”, “one of A, B, C, or a combination thereof” and “one of A, B, C, and a combination thereof” refer to each component and a combination thereof (e.g., A; B; A and B; A and C; B and C; or A, B, and C). For example, “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As utilized herein, alternative language such as “or” is not to be construed as an exclusive meaning, for example, “A or B” is construed to include A, B, A+B, and/or the like. Similarly, the term “and/or” includes any and all combinations of one or more of the associated listed items. The symbol “/” utilized herein may be interpreted as “and” or “or” according to the context.

As utilized herein, it is to be understood that the terms such as “including,” “includes,” “include,” “having,” “has,” “have,” “comprises,” “comprise,” and/or “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added. The term “combination thereof may include a mixture, a laminate, a complex, a copolymer, an alloy, a blend, a reactant of constituents.

As utilized herein, singular forms such as “a,” “an,” and “the” are intended to include the plural forms as well, unless the context clearly indicates otherwise.

As utilized herein, the terms “use,” “using,” and “used” may be considered synonymous with the terms “utilize,” “utilizing,” and “utilized,” respectively.

The term “may” will be understood to refer to “one or more embodiments of the present disclosure,” some of which include the described element and some of which exclude that element and/or include an alternate element. Similarly, alternative language such as “or” refers to “one or more” or “some” “embodiments of the present disclosure,” each including a corresponding listed item.

In this context, “consisting essentially of” means that any additional components will not materially affect the chemical, physical, optical or electrical properties of the semiconductor film.

### Definitions

As used herein, if (e.g., when) a definition is not otherwise provided, “substituted” refers to replacement of a hydrogen atom of a compound by a substituent selected from among a halogen atom (F, Br, Cl, or I), a hydroxyl group, a thiol group, a nitro group, a cyano group, an amino group, a substituted or unsubstituted C1 to C30 amine group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 allyl group, a C1 to C30 alkoxy group, a C1 to C30 sulfide group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and/or a (e.g., any suitable) combination thereof.

As used herein, if (e.g., when) a definition is not otherwise provided, “an alkyl group” refers to a linear or branched aliphatic hydrocarbon group. The alkyl group may be “a saturated alkyl group” without any double bond or triple bond.

The alkyl group may be a C1 to C20 alkyl group. For example, the alkyl group may be a C1 to C10 alkyl group or a C1 to C6 alkyl group. For example, the C1 to C5 alkyl group refers to that the alkyl chain contains 1 to 5 carbon atoms and is selected from among methyl, ethyl, propyl, iso-propyl, n-butyl, iso-butyl, sec-butyl, and tert-butyl.

The alkyl group refers to specific examples that are a methyl group, an ethyl group, a propyl group, an isopropyl group, a butyl group, an isobutyl group, a tert-butyl group, a pentyl group, a hexyl group, and/or the like.

In chemical formulas described herein, t-Bu refers to a tert-butyl group.

As used herein, if (e.g., when) a definition is not otherwise provided, “cycloalkyl group” refers to a monovalent cyclic aliphatic hydrocarbon group.

The cycloalkyl group refers to a cyclopropyl group, a cyclobutyl group, a cyclopentyl group, a cyclohexyl group, and/or the like.

The cycloalkyl group may be a C3 to C10 cycloalkyl group, for example, a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but the present disclosure is not limited thereto.

As used herein, unless otherwise defined, “alkenyl group” refers to an aliphatic unsaturated alkenyl group including at least one double bond as a linear or branched aliphatic hydrocarbon group.

As used herein, unless otherwise defined, “alkynyl group” refers to an aliphatic unsaturated alkynyl group including at least one triple bond as a linear or branched aliphatic hydrocarbon group.

As used herein, “aryl group” refers to a substituent in which all atoms in the cyclic substituent have a p-orbital and these p-orbitals are conjugated and may include a monocyclic or fused ring polycyclic functional group (i.e., rings sharing adjacent pairs of carbon atoms) functional group.

As used herein, if (e.g., when) a definition is not otherwise provided, “hetero” refers to one including 1 to 3 heteroatoms selected from among N, O, S, Se, and P.

In the present disclosure, if (e.g., when) a definition is not otherwise provided, “heterocycloalkyl group” refers to a cycloalkyl group containing at least one hetero atom selected from among N, O, S, P, and Si.

In the present disclosure, “heteroaryl group” refers to an aryl group including at least one hetero atom selected from among N, O, S, P, and Si. Two or more heteroaryl groups are linked by a sigma bond directly, or if (e.g., when) the heteroaryl group includes two or more rings, the two or more rings may be fused. When the heteroaryl group is a fused ring, each ring may include 1 to 3 hetero atoms.

In some embodiments, in this specification, acrylic polymer refers to acrylic polymer and methacrylic polymer.

Unless otherwise specified in the present specification, the weight average molecular weight is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

In some embodiments, unless otherwise defined in the specification, indicates a linking point of a structural unit or a compound moiety of a compound.

Hereinafter, a resist topcoat composition according to one or more embodiments is described.

### Resist Topcoat Composition

The described technology relates generally to a resist topcoat composition and a method of forming a pattern (e.g., patterns (e.g., photoresist patterns)) using the a resist topcoat composition, which may improve sensitivity of the photoresist during the photolithography micropattern formation process using high-energy rays such as EUV (extreme ultraviolet; wavelength of 13.5 nm) and may concurrently (e.g., at the same time) selectively reduce an acid concentration in the upper layer of the photoresist, to improve IPU (in-point uniformity) of C/H (contact hole) patterns, LER (line edge roughness)/LWR (line width roughness) of US (line and space) patterns, and IPU of pillar patterns. That is, embodiments of the present disclosure pertain to a photoresist topcoat composition and a method for forming patterns, including photoresist patterns, utilizing the resist topcoat. This composition enhances the photoresist's sensitivity during the photolithography micropattern formation process involving high-energy rays, such EUV. Concurrently, it selectively reduces acid concentration in the photoresist's upper layer, thereby improving in-point uniformity (IPU) for contact hole (C/H) patterns, reducing line edge roughness (LER) and line width roughness (LWR) for line and space (US) patterns, and enhancing IPU for pillar patterns.

For example, a resist topcoat composition according to one or more embodiments includes a copolymer including a first structural unit represented by Chemical Formula M-1 and a second structural unit represented by Chemical Formula M-2, an amide-based matting agent, and a solvent.

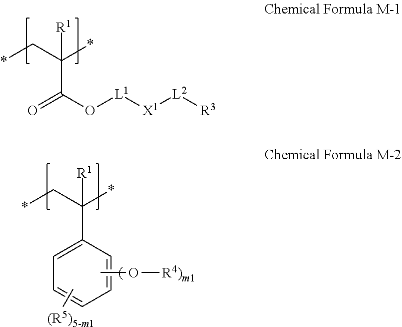

In Chemical Formula M-1 and Chemical Formula M-2,
R¹ and R² may each independently be hydrogen or a substituted or unsubstituted C1 to C10 alkyl group,
L¹ and L² may each independently be a single bond, a substituted or unsubstituted C1 to C10 alkylene group, and/or a (e.g., any suitable) combination thereof,
X¹ may be a single bond, —O—, —S—, —S(O)—, —S(O)₂—, —C(O)—, —(CO)O—, —O(CO), —O(CO)O—, —NR^{a}— (wherein, R^{a} is hydrogen, deuterium, or a substituted or unsubstituted C1 to C10 alkyl group), and/or a (e.g., any suitable) combination thereof,
R³ may be hydrogen, fluorine, a hydroxyl group, a substituted or unsubstituted C1 to C20 alkyl group, and/or a (e.g., any suitable) combination thereof,
R⁴ may be hydrogen, or C(═O)R^{b},
R^{b} may be a substituted or unsubstituted C1 to C10 alkyl group, at least one selected from among R³, L¹, and L² includes fluorine and a hydroxyl group,
R⁵ may be hydrogen, a halogen, a hydroxyl group, a substituted or unsubstituted C1 to C10 alkyl group, and/or a (e.g., any suitable) combination thereof,
m1 may be any one of the integers from 1 to 4, and
* is a linking point.

The resist topcoat composition according to one or more embodiments is coated on the photoresist layer to not only increase the sensitivity of the photoresist, but to also greatly improve the line edge roughness (LER) and line width roughness (LWR) of line and space (L/S) patterns, the in-point uniformity (IPU) of contact hole (C/H) patterns, and/or the IPU of pillar patterns.

In some embodiments, by using the amide-based matting agent, amine groups are selectively exposed in the exposed region through exposure on the upper portion of the photoresist layer, and the exposed amine selectively removes the activated acid on the exposed region. As a result, the rounded profile of the deteriorated region on the upper part of the pattern that occurred during the exposure process may be improved, that is, the upper layer of the photoresist, by making it rectangular, and thus the IPU or LWR of the pattern may be improved. That is, employing an amide-based matting agent facilitates the selective exposure of amine groups within the upper region of the photoresist layer. This targeted exposure allows the amine groups to selectively neutralize the activated acid in the region. As a result, the rounded profile of the pattern's deteriorated upper portion, which typically occurs during the exposure process, can be transformed into a more rectangular shape. This modification significantly enhances the in-point uniformity (IPU) and/or reduces the line width roughness (LWR) of the pattern.

The first structural unit included in the copolymer of the resist topcoat composition may protect the photoresist while minimizing or reducing an effect or impact on the photoresist. For example, the first structural unit may have the ability to dissolve well in a solvent that has little reactivity with the photoresist, and the second structural unit may further enhance or improve sensitivity by increasing EUV absorption.

Accordingly, the copolymer may have excellent or suitable solubility in solvents, may be uniformly (e.g., substantially uniformly) coated on at least one pattern, and may minimize or reduce an impact or effect on the resist.

As an example, the copolymer may include a first structural unit represented by Chemical Formula M-1 and a second structural unit represented by Chemical Formula M-2.

In Chemical Formula M-2, if (e.g., when) m1 is 2 or more, each O—R⁴ may be the same or different from each other.

In Chemical Formula M-2, if (e.g., when) 5-m1 is 2 or more, each R⁵ may be the same or different from each other.

The meaning (e.g., phrase) that “at least one selected from among R³, L¹, and L² includes a fluorine and a hydroxyl group” as used herein indicates, or may include, cases where,
R³ may be a C1 to C20 alkyl group substituted with at least one fluorine and at least one hydroxyl group, or
at least one selected from among L¹ and L² may be a C1 to C10 alkylene group substituted with at least one (e.g., one or more) fluorine and one or more hydroxyl groups, or
at least one selected from among L¹ and L² may be a C1 to C10 alkylene group substituted with at least one (e.g., one or more) fluorine, and at least one of the others (e.g., one selected from among any remaining L¹ and L²) may be a C1 to C10 alkylene group substituted with at least one (e.g., one or more) hydroxyl groups, or
R³ may be fluorine, and at least one selected from among L¹ and L² may be a C1 to C10 alkylene group substituted with at least one (e.g., one or more) hydroxyl groups, or
R³ may be a hydroxyl group, and at least one selected from among L¹ and L² may be a C1 to C10 alkylene group substituted with at least one (e.g., one or more) fluorine, or
R³ may be a C1 to C10 alkyl group substituted with at least one (e.g., one or more) fluorine and at least one (e.g., one or more) hydroxyl groups, or
R³ may be a C1 to C10 alkyl group substituted with at least one (e.g., one or more) hydroxyl groups and at least one (e.g., one or more) C1 to C10 fluoroalkyl groups.

As a an example, the first structural unit may be represented by Chemical Formula 1.

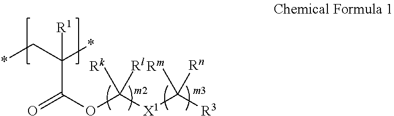

In Chemical Formula 1,
R¹ may be hydrogen or a substituted or unsubstituted C1 to C10 alkyl group,
R^{k}, R^{l}, R^{m}, Rⁿ, and R³ may each independently be hydrogen, fluorine, a hydroxyl group, a substituted or unsubstituted C1 to C20 alkyl group, and/or a (e.g., any suitable) combination thereof,
m2 and m3 may each independently be an integer from 1 to 10,
X¹ may be a single bond, —O—, —S—, —S(O)—, —S(O)₂—, —C(O)—, —(CO)O—, —O(CO), —O(CO)O—, —NR^{a}— (wherein, R^{a} is hydrogen, deuterium, or a substituted or unsubstituted C1 to C10 alkyl group), and/or a (e.g., any suitable) combination thereof, and

at least one selected from among R^{k}, R^{l}, R^{m}, Rⁿ, and R³ includes fluorine and a hydroxyl group.

In Chemical Formula 1, if (e.g., when) m2 is 2 or more, each R^{k} may be the same or different from each other.

In Chemical Formula 1, if (e.g., when) m2 is 2 or more, each R^{l} may be the same or different from each other.

In Chemical Formula 1, if (e.g., when) m3 is 2 or more, each R^{m} may be the same or different from each other.

In Chemical Formula 1, if (e.g., when) m3 is 2 or more, each Rⁿ may be the same or different from each other.

The meaning (e.g., phrase) that “at least one selected from among R^{k}, R^{l}, R^{m}, Rⁿ, and R³ includes a fluorine and a hydroxyl group” as used herein indicates, or may include, cases where:
at least one selected from among R^{k}, R^{l}, R^{m}, Rⁿ, and R³ is may each independently be a fluorine and hydroxyl group, or
at least one selected from among R^{k}, R^{l}, R^{m}, Rⁿ, and R³ may each independently include a C1 to C10 alkyl group substituted with at least one (e.g., one or more) fluorine and a C1 to C10 alkyl group substituted with at least one (e.g., one or more) hydroxyl groups, or
at least one selected from among R^{k}, R^{l}, R^{m}, Rⁿ, and R³ may each independently include at least one (e.g., one or more) hydroxyl groups and at least one (e.g., one or more) C1 to C10 alkyl groups substituted with fluorine, or
at least one selected from among R^{k}, R^{l}, R^{m}, Rⁿ, and R³ may each independently include a C1 to C5 alkyl group substituted with at least one (e.g., one or more) hydroxyl groups and at least one (e.g., one or more) C1 to C5 fluoroalkyl groups, or
at least one selected from among R^{k}, R^{l}, R^{m}, Rⁿ, and R³ may be fluorine, and at least one of the others (e.g., one selected from among any remaining R^{k}, R^{l}, R^{m}, Rⁿ, and R³) may be a hydroxyl group, or
at least one selected from among R^{k}, R^{l}, R^{m}, Rⁿ, and R³ may be fluorine, and at least one of the others may include a C1 to C10 alkyl group substituted with at least one (e.g., one or more) hydroxyl groups, or
at least one selected from among R^{k}, R^{l}, R^{m}, Rⁿ, and R³ may be a hydroxyl group, and at least one of the others may include a C1 to C10 alkyl group substituted with at least one (e.g., one or more) fluorines, or
at least one selected from among R^{k}, R^{l}, R^{m}, Rⁿ, and R³ may be a C1 to C20 alkyl group substituted with at least one (e.g., one or more) fluorine, and at least one of the others may be a C1 to C20 alkyl group substituted with at least one (e.g., one or more) hydroxyl groups.

For example, R¹ may be hydrogen or a methyl group,
X¹ may be a single bond, —O—, or —NR^{a}— (wherein, R^{a} is hydrogen, deuterium, or a substituted or unsubstituted C1 to C10 alkyl group), and

R³ may be fluorine, a hydroxyl group, a C1 to C10 alkyl group substituted with at least one fluorine, or a C1 to C10 alkyl group substituted with at least one hydroxyl group.

As an example, in Chemical Formula 1, at least one selected from among R^{m}, Rⁿ, and R³ may include a fluorine and a hydroxyl group.

As an example, in Chemical Formula 1, at least one selected from among R^{m} and Rⁿ may be fluorine or a C1 to C10 alkyl group substituted with at least one fluorine, and R⁵ may be a hydroxyl group or a C1 to C10 alkyl group substituted with at least one hydroxyl group.

As an example, in Chemical Formula 1, at least one selected from among R^{m} and Rⁿ may be a hydroxyl group or a C1 to C10 alkyl group substituted with at least one hydroxyl group, and R³ may be fluorine or a C1 to C10 alkyl group substituted with at least one fluorine.

As an example, in Chemical Formula 1, R^{m} may be a hydroxyl group or a C1 to C10 alkyl group substituted with at least one hydroxyl group, Rⁿ may be fluorine or a C1 to C10 alkyl group substituted with at least one fluorine, and R³ may be a hydroxyl group, fluorine, or a C1 to C10 alkyl group substituted with at least one of fluorine and hydroxyl groups.

As an example, in Chemical Formula 1, at least one selected from among R^{m} and Rⁿ may be fluorine or a C1 to C10 alkyl group substituted with at least one fluorine, and R³ may be a hydroxyl group or a C1 to C5 alkyl group substituted with at least one of a hydroxyl group and a C1 to C5 fluoroalkyl group.

For example, the first structural unit may be any one selected from among Group I.

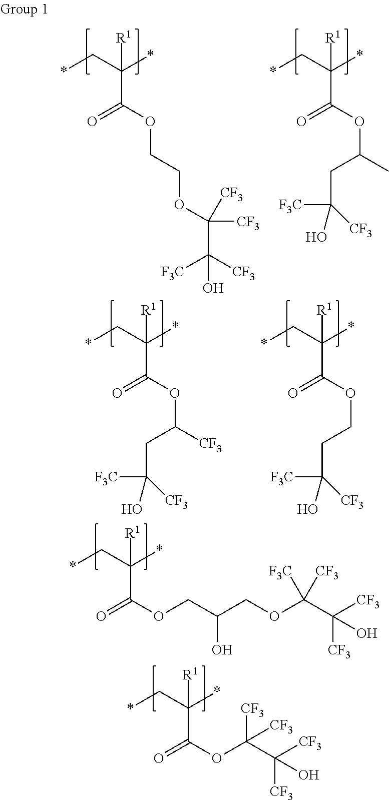

In Group I,
each R¹ may independently be hydrogen or a methyl group, and * is a linking point.

As an example, the second structural unit may be represented by any one of Chemical Formula 2-1 to Chemical Formula 2-4.

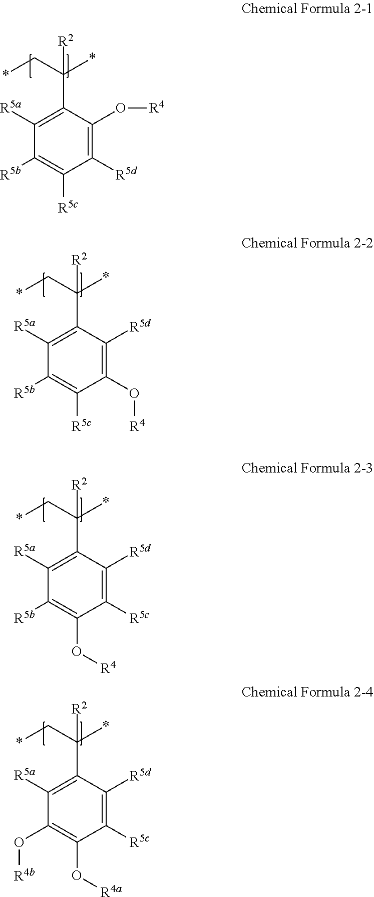

In Chemical Formula 2-1 to Chemical Formula 2-4,
R² may be hydrogen or a methyl group,
R⁴, R^{4a}, and R^{4b} may each independently be hydrogen or C(═O)R^{b},
R^{b} may be a substituted or unsubstituted C1 to C5 alkyl group,
R^{5a}, R^{5b}, R^{5c}, and R^{5d} may each independently be hydrogen, a halogen, a hydroxyl group, a substituted or unsubstituted C1 to C10 alkyl group, and/or a (e.g., any suitable) combination thereof, and
* is a linking point.

As an example, at least one of R⁵ may be a halogen.

As an example, at least one of R⁵ may be an iodine group.

If (e.g., when) the second structural unit includes an iodine group, sensitivity may be further enhanced or improved.

For example, the second structural unit may be any one selected from among Group II.

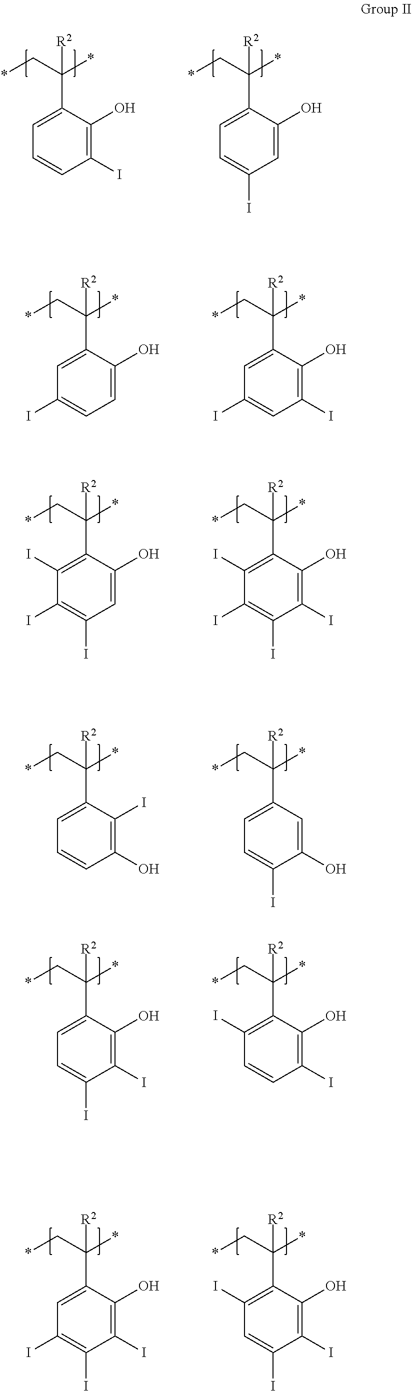

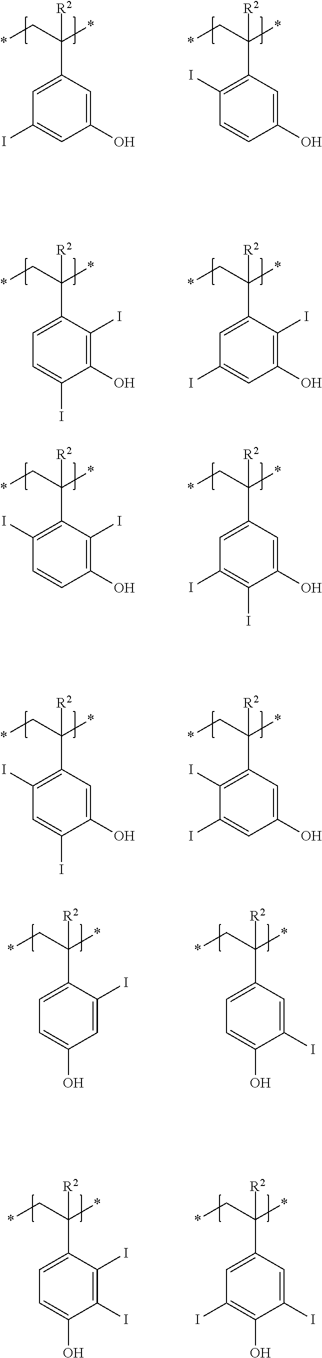

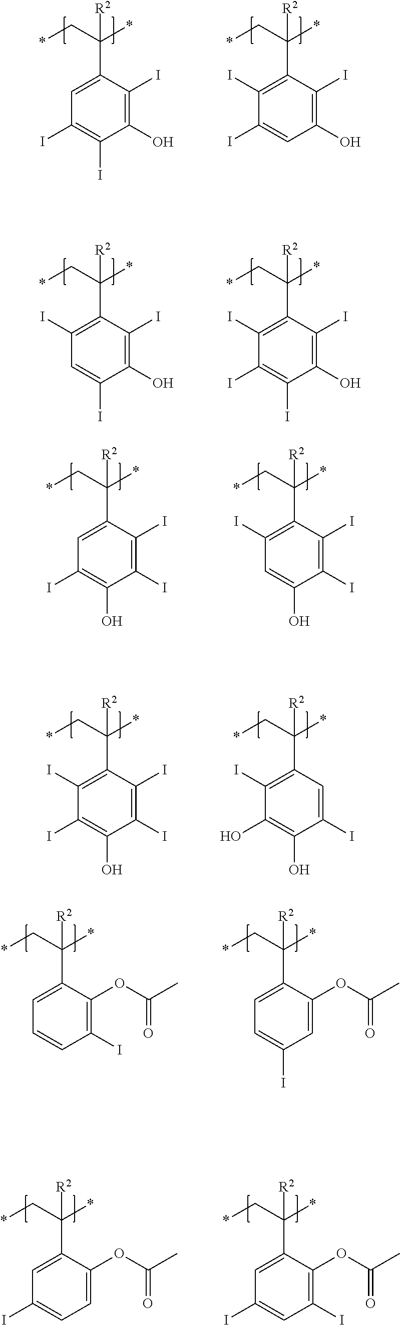

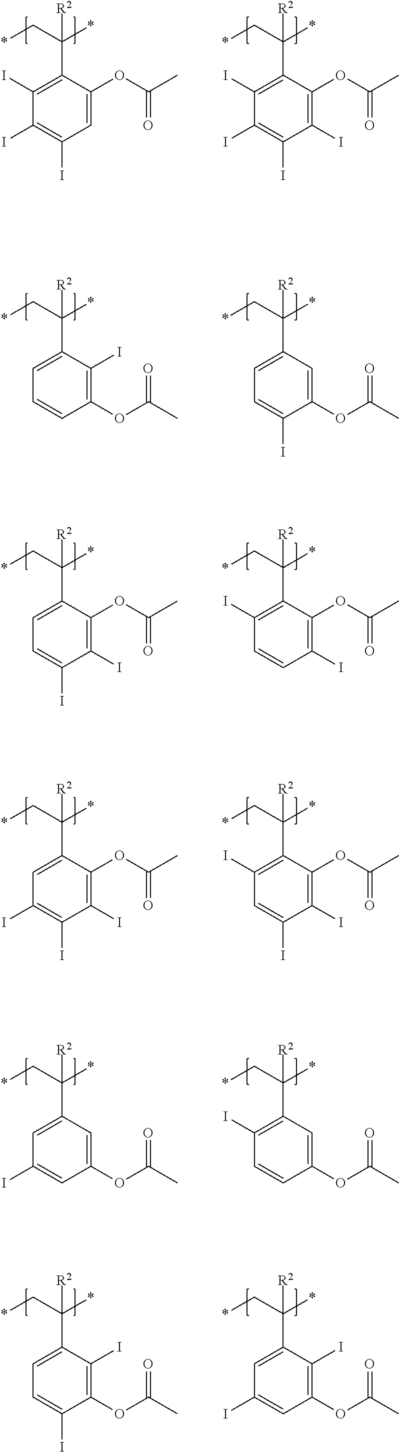

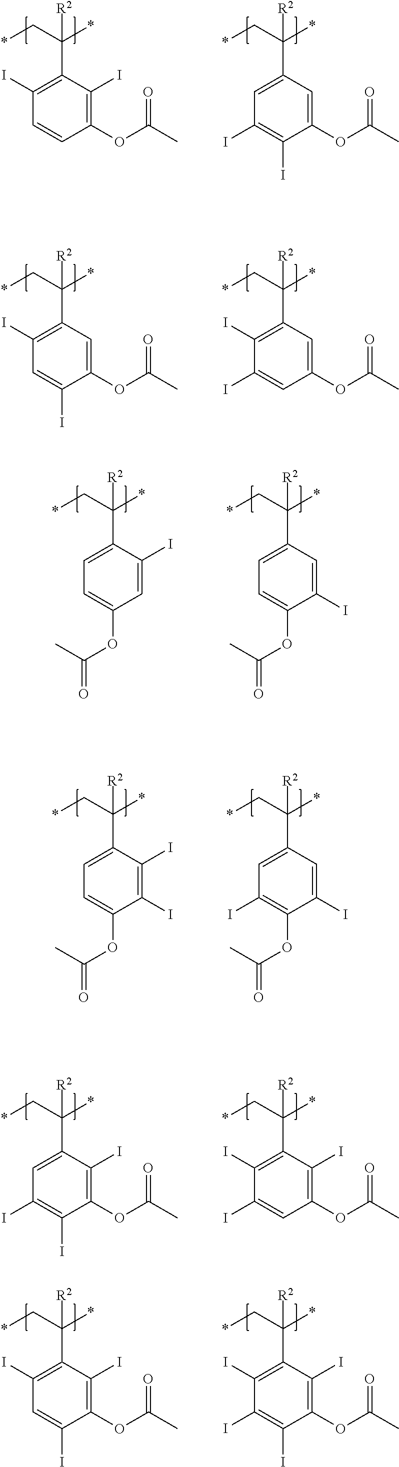

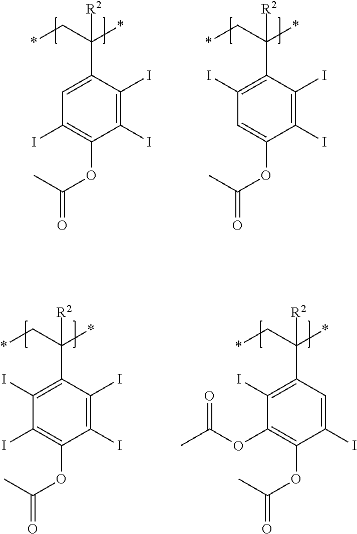

In Group II,
each R² may independently be hydrogen or a methyl group and * is a linking point.

The copolymer may include about 50 to about 99 mol % of the first structural unit and about 1 to about 50 mol % of the second structural unit.

For example, the copolymer may include about 70 to about 99 mol % of the first structural unit, about 1 to about 30 mol % of the second structural unit, e.g., about 80 to about 95 mol % of the first structural unit, and about 5 to about 20 mol % of the second structural unit.

If (e.g., when) the mole ratio of each structural unit included in the copolymer is within the described ranges, the solubility in organic solvents may be enhanced or improved and the pattern(s) can be uniformly (e.g., substantially uniformly) coated.

The copolymer may have a weight average molecular weight (Mw) of about 1,000 g/mol to about 50,000 g/mol. For example, it may have a weight average molecular weight of about 2,000 g/mol to about 30,000 g/mol, for example, about 3,000 g/mol to about 20,000 g/mol, or for example about 4,000 g/mol to about 10,000 g/mol, but the present disclosure is not limited thereto. If (e.g., when) the weight average molecular weight of the copolymer is within the described ranges, a carbon content (e.g., amount) and solubility in a solvent of the resist topcoat composition including the copolymer may be improved or optimized.

The copolymer may be included in an amount of about 0.1 wt % to about 10 wt % based on a total weight of the resist topcoat composition. Within the described range, the resist topcoat may be easily removed.

In one or more embodiments, the copolymer may be any one selected from among any one of those listed in Group 11.

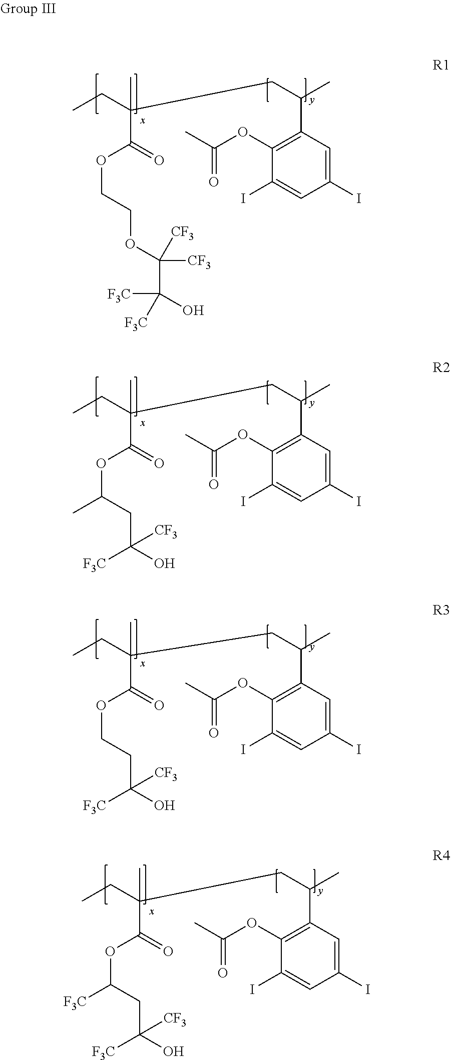

In Group III, x:y may be about 99:1 to 90:10, for example, about 99:1, about 96:4, about 95:5, about 91:9, or about 90:10.

An amide-based matting agent according to one or more embodiments may be a cyclic amide or a derivative thereof. For example, it may be one selected from among a cyclic amine, a derivative thereof, a cyclic amide, and a derivative thereof which are protected with a protecting group. The amine group of the amide-based matting agent may be exposed during exposure, thereby selectively quenching the acid generated in the upper portion of the photoresist in the exposed region of the amine group, thereby improving the profile of the patterns and improving IPU or LWR.

The amide-based matting agent according to one or more embodiments may be any one (e.g., may include at least one) of (e.g., selected from among) the compounds represented by Chemical Formula 3 and Chemical Formula 4.

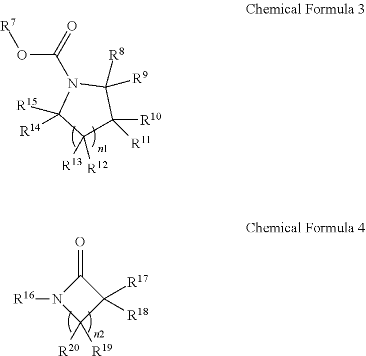

In Chemical Formula 3 and Chemical Formula 4,
R⁷ may be a substituted or unsubstituted C1 to C20 alkyl group or a substituted or unsubstituted C3 to C20 cycloalkyl group,
R⁸ to R²⁰ may each independently be hydrogen, a halogen, a hydroxyl group, a substituted or unsubstituted C1 to C20 alkyl group, a substituted or unsubstituted C3 to C20 cycloalkyl group, a substituted or unsubstituted C1 to C20 alkoxy group, a substituted or unsubstituted C6 to C30 aryl group, and/or a (e.g., any suitable) combination thereof,
n1 may be any one of integers of 1 to 3, and
n2 may be any one of integers of 1 to 4.

For example, R⁷ and R¹⁶ may each independently be a substituted or unsubstituted C1 to C10 alkyl group or a substituted or unsubstituted C3 to C10 cycloalkyl group.

As an example, R⁷ and R¹⁶ may each independently be a methyl group, an ethyl group, an n-propyl group, an iso-propyl group, an n-butyl group, a sec-butyl group, a tert-butyl group, an n-pentyl group, a tert-pentyl group, a neo-pentyl group, an iso-pentyl group, a sec-pentyl group, a cyclobutyl group, a cyclopentyl group, or a cyclohexyl group.

In one or more embodiments, R⁷ may be a tert-butyl group.

The amide-based matting agent may be at least one of the compounds listed in Group IV.

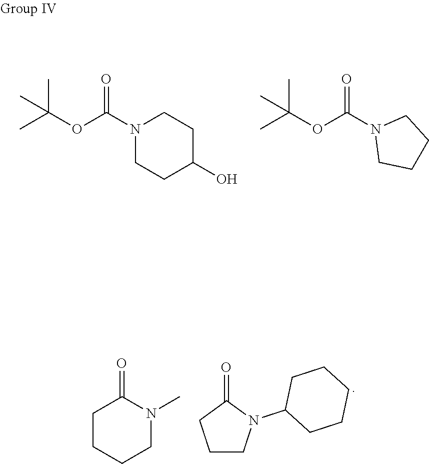

The amide-based matting agent may be included in an amount of about 0.1 parts by weight to about 40 parts by weight, for example about 0.1 parts by weight to about 30 parts by weight, for example about 0.5 parts by weight to about 30 parts by weight based on 100 parts by weight of the copolymer. Within the described range, solubility can be improved or optimized and pattern LWR improvement effect can be secured.

Additionally, the resist topcoat composition may further include at least one other polymer selected from among an epoxy-based resin, a novolac (phenol-formaldehyde-based) resin, a glycoluril-based resin, and a melamine-based resin, but the present disclosure is not limited thereto. That is, The resist topcoat composition may also contain other polymers, such as epoxy-based, novolac, glycoluril-based, or melamine-based resins.

The resist topcoat composition may further include an additive including a surfactant, a thermal acid generator, a plasticizer, and/or a (e.g., any suitable) combination thereof.

The surfactant may be, for example, an alkylbenzene sulfonic acid salt, an alkylpyridinium salt, polyethylene glycol, a quaternary ammonium salt, and/or the like, but the present disclosure is not limited thereto.

The thermal acid generator may be, for example, an acid compound such as p-toluene sulfonic acid, trifluoromethanesulfonic acid, pyridinium p-toluene sulfonic acid, salicylic acid, sulfosalicylic acid, citric acid, benzoic acid, hydroxybenzoic acid, naphthalene carboxylic acid and/or benzoin tosylate, 2-nitrobenzyl tosylate, and other organic sulfonic acid alkyl esters, but the present disclosure is not limited thereto.

The amount of these additives used can be easily adjusted according to desired or suitable physical properties and may not be provided.

The solvent may be an ether-based solvent, and is, for example, represented by Chemical Formula 5.

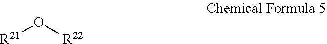

In Chemical Formula 5,
R²¹ and R²² may each independently be a substituted or unsubstituted C3 to C20 alkyl group.

For example, the ether-based solvent may be selected from among diisopropyl ether, dipropyl ether, diisoamyl ether, diamyl ether, dibutyl ether, diisobutyl ether, di-sec-butyl ether, dihexyl ether, bis(2-ethylhexyl) ether, didecyl ether, diundecyl ether, didodecyl ether, ditetradecyl ether, hexadecyl ether, butyl methyl ether, butyl ethyl ether, butyl propyl ether, tert-butyl methyl ether, tert-butyl ethyl ether, tert-butylpropyl ether, di-tert-butyl ether, cyclopentylmethyl ether, cyclohexylmethyl ether, cyclopentylethyl ether, cyclohexylethyl ether, cyclopentylpropyl ether, cyclopentyl-2-propyl ether, cyclohexylpropyl ether, cyclohexyl-2-propyl ether, cyclopentylbutyl ether, cyclopentyl-tert-butyl ether, cyclohexylbutyl ether, cyclohexyl-tert-butyl ether, and/or a (e.g., any suitable) combination thereof.

The ether-based solvent may have sufficient solubility or dispersibility for the aforementioned resist topcoat composition.

In one or more embodiments, according to some example embodiments, a method of forming patterns using the aforementioned resist topcoat composition may be provided. For example, the manufactured patterns may be resist patterns (e.g., photoresist patterns).

A method of forming resist patterns according to some example embodiments includes coating and heating a photoresist composition on a substrate to form a photoresist layer, coating and heating the aforementioned resist topcoat composition on the photoresist layer to form a topcoat, and exposing and developing the topcoat and the photoresist layer to form patterns (e.g., resist patterns).

Hereinafter, a method of forming patterns using the aforementioned resist topcoat composition will be described with reference to the drawing, which a schematic view for explaining a method of forming patterns using the resist topcoat composition according to the present disclosure.

Referring to the drawing, first, a substrate (e.g., object) 100 to be etched is prepared. A non-limiting example of the substrate (e.g., object) 100 to be etched may include or be a thin film formed on a semiconductor substrate. Hereinafter, only the case where the substrate (e.g., object) 100 to be etched is a thin film will be described. The surface of the thin film is cleaned to remove contaminants remaining on the thin film. The thin film may be, for example, a silicon nitride film, a polysilicon film, or a silicon oxide film.

A photoresist composition is coated on the thin film and heated to form a photoresist layer 101 (e.g., shown at 1). Subsequently, the photoresist topcoat composition is coated on the photoresist layer and heated to form a topcoat 30 (e.g., photoresist topcoat) (e.g., shown at 2).

The heating may be performed at a temperature of about 80° C. to about 500° C.

Then, the topcoat (e.g., photoresist topcoat) and the photoresist layer are exposed to high-energy radiation.

For example, the high-energy radiation that may be used in the exposure process may include light having a high-energy wavelength, such as EUV (Extreme Ultraviolet radiation; wavelength: 13.5 nanometer (nm)) and/or E-Beam (electron beam) radiation. That is, the exposure process may utilize radiation with high-energy wavelengths, including EUV (wavelength: 13.5 nm) and/or E-Beam.

A post-exposure heat treatment (PEB) is then performed. The post-exposure heat treatment may be performed at a temperature of about 80° C. to about 200° C. By performing the post-exposure heat treatment, at least one exposed region of the photoresist layer, (that is, the region(s) not covered by the patterned mask) is changed to a be soluble (e.g., have a property or characteristic that is soluble) in a developer, so that the solubility of the exposed region(s) may be different from the solubility of the unexposed region of the photoresist layer.

At least one resist pattern 102b may be formed by dissolving and removing the photoresist layer corresponding to the exposed region(s) and the topcoat (e.g., photoresist topcoat) using a developer (e.g., shown at 3).

For example, the developer may be at least one of an alkaline developer or a developer that may include (e.g., containing) an organic solvent (hereinafter referred to as an organic-based developer).

As the alkaline developer, at least one quaternary ammonium salt (e.g., such as tetramethylammonium hydroxide) may be (e.g., is usually) used, or aqueous alkaline solutions including at least one selected from among inorganic alkalis, primary to tertiary amines, alcohol amines, and cyclic amines may also be used.

Moreover, the alkaline developer may contain alcohol and/or surfactant in an appropriate or suitable amount. An concentration of an alkaline component of the alkaline developer may be, for example, about 0.1 to about 20 mass %, based on a total amount of the alkaline developer. A pH of the alkaline developer may be, for example, about 10 to about 15.

The organic-based developer may be a developer containing at least one organic solvent selected from among the group consisting of ketone solvents, ester solvents, alcohol solvents, amide solvents, ether solvents, and hydrocarbon solvents.

Examples of the ketone solvent may include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonyl acetone, ionone, diacetonyl alcohol, acetyl carbinol, acetophenone, methyl naphthyl ketone, isophorone, propylene carbonate, and/or the like.

Examples of the ester solvent may include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, ethylene glycol monobutyl ether acetate, ethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, butyl propionate, and/or the like.

Suitable solvents may be used as alcohol solvents, amide solvents, ether solvents, and hydrocarbon solvents.

A plurality of said solvents may be mixed, or may be mixed with solvents or water other than the described solvents.

A moisture (i.e., water) content (e.g., amount) (e.g., as a whole) of the developer may be less than about 50 wt %, less than about 20 wt %, or less than about 10 wt %, based on a total amount of the organic developer. In one or more embodiments, the developer may exclude (e.g., be substantially free of) moisture (i.e., water).

A content (e.g., amount) of the organic solvent may be desirably about 50 to about 100 wt %, more desirably about 80 to about 100 wt %, still more desirably about 90 to about 100 wt %, and particularly desirably about 95 to about 100 wt % based on a total amount of the organic developer.

The organic developer may include an appropriate or suitable amount of a suitable surfactant as desired or required.

A content (e.g., amount) of the surfactant may be usually about 0.001 to about 5 wt %, desirably about 0.005 to about 2 wt %, and more desirably about 0.01 to about 0.5 wt % based on a total amount of the developer.

The organic developer may include the aforementioned inhibitor.

Subsequently, the exposed thin film is etched by applying the photoresist pattern as an etching mask. As a result, the thin film is formed into at least one thin film pattern(s).

The thin film may be etched, for example, by dry etching using an etching gas, and the etching gas may be, for example, CHF₃, CF₄, Cl₂, BCl₃, and/or a (e.g., any suitable) mixture thereof.

In the exposure process performed as described, the thin film patterns formed using the photoresist pattern that is formed by the exposure process performed using the EUV light source may have a width corresponding to the photoresist pattern. For example, the photoresist pattern may have a width of about 5 nm to about 100 nm. For example, the thin film patterns formed by the exposure process performed using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, and may be formed, for example, in a width of less than or equal to about 20 nm, and which may be similar to the width of the photoresist pattern.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

Hereinafter, the present disclosure will be described in more detail through examples relating to the synthesis of the aforementioned polymer and the preparation of a resist topcoat composition including the same. However, the present disclosure is not technically limited by the following examples.

### EXAMPLES

### Synthesis Examples

### Synthesis Example 1: Synthesis of Compound 1a

20 g (59.86 mmol) of hexafluoro-2,3-bis(trifluoromethyl)-2,3-butanediol(perfluoropinacol), 7.79 g (59.86 mmol) of 2-(hydroxyethyl)methacrylate, and 18.84 g (71.84 mmol) of triphenylphosphine (Ph₃P) were mixed in 110 mL of diethylether under a nitrogen atmosphere and then, stirred. After the stirring for 30 minutes, the mixture was cooled down to 0° C., and another mixture of 14.52 g (71.84 mmol) of diisopropyl azodicarboxylate (DIAD) and 35 mL of diethylether was slowly added thereto over 2 hours. Subsequently, the obtained mixture was stirred at room temperature (23° C.) for 24 hours and then, concentrated. The concentrated mixture was dissolved in dichloromethane and then, treated through column chromatography by using silica gel to separate a synthesized material. The separated material was distilled under a reduced pressure, obtaining a product 2-[3,3,3-trifluoro-2-hydroxy-1,1,2-tris(trifluoromethyl)propoxy]ethyl 2-methyl-2-propenoate represented by Chemical Formula 1a.

¹H-NMR of the preceding product: (Acetone-d6): δ1.90 (3H, t), 4.36 (4H, m), 5.63 (1H, t), 6.09 (1H, t), 8.34 (1H, s)

¹⁹F-NMR of the preceding product: (Acetone-d6): δ −70.12 (6F, m), −65.38 (6F, m)

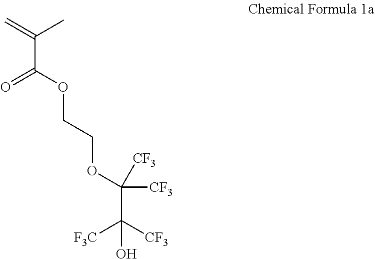 [SMILES: C=C(C)C(=O)OCCOC(C(F)(F)F)(C(F)(F)F)C(O)(C(F)(F)F)C(F)(F)F]

### Synthesis Example 2: Preparation of Copolymer R1

In a 250 mL 2-neck round bottom flask, a compound represented by Chemical Formula 1a (16.1 g, 36 mmol), a compound represented by Chemical Formula 1 b (DIVPA, Songwon) (1.7 g, 4 mmol), and 110 g of diisoamyl ether (DIAE) were added under a nitrogen atmosphere and then, heated to 100° C. When the internal temperature reached 85° C., 14.7 g of a 25 wt % V-601/DIAE solution (V-601, 3.7 g, 16 mmol) was slowly added thereto, and after 6 hours, the reaction solution was cooled to room temperature and then, concentrated to have a solid content (e.g., amount) of 50%. 270 g of heptane was added to the concentrated solution, and a polymer produced therefrom was filtered. The filtered polymer was completely dissolved in 34 g of DIAE, and 270 g of heptane was added thereto for precipitation, which were twice repeated to obtain precipitates, and the precipitates were completely dried, preparing final Copolymer R1 (Mw=4,000).

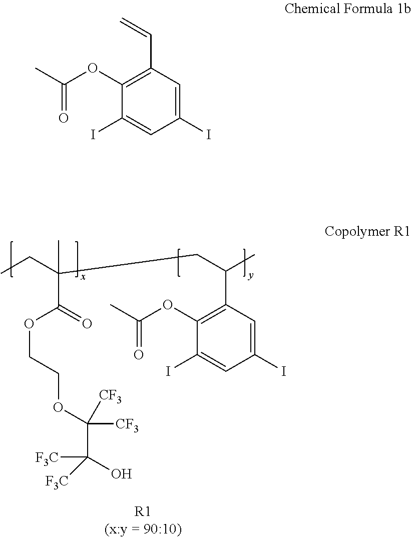

### Synthesis Example 3: Preparation of Copolymer R2

Copolymer R2 (Mw=9,000) was prepared in substantially the same manner as in Synthesis Example 2 except that a compound represented by Chemical Formula 2b (1.5 g, 16 mmol) (2,4-diiodo-6-vinylphenol, Accela Chembio Inc.) was used instead of the compound represented by Chemical Formula 1 b.

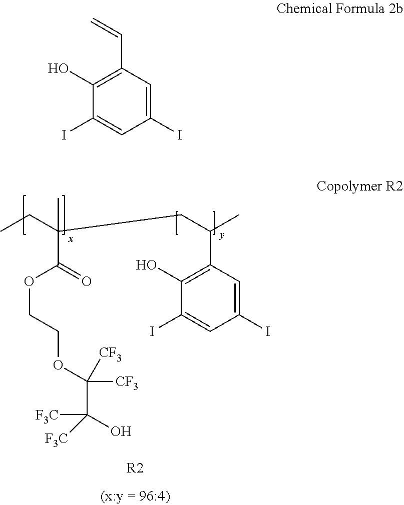

### Synthesis Example 4: Preparation of Copolymer R3

Copolymer R3 (Mw=5,000) was prepared in substantially the same manner as in Synthesis Example 2 except that a compound represented by Chemical Formula 2a (10.6 g, 36 mmol) was used instead of the compound represented by Chemical Formula 1 b.

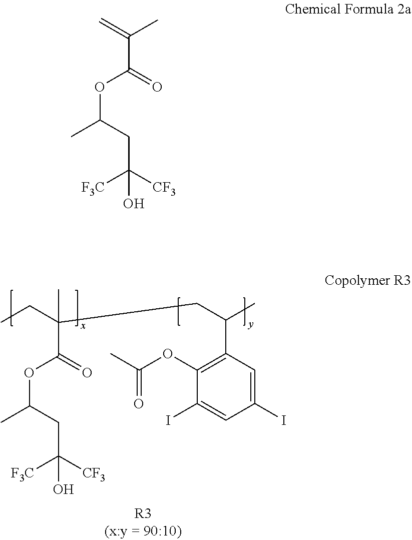

### Synthesis Example 5: Preparation of Copolymer R4

Copolymer R4 (Mw=6,000) was prepared in substantially the same manner as in Synthesis Example 2 except that a compound represented by Chemical Formula 2a (16.1 g, 36 mmol) instead of the compound represented by Chemical Formula 1a and a compound (1.5 g, 4 mmol) represented by Chemical Formula 2b (16.1 g, 36 mmol) instead of the compound represented by Chemical Formula 1b were used.

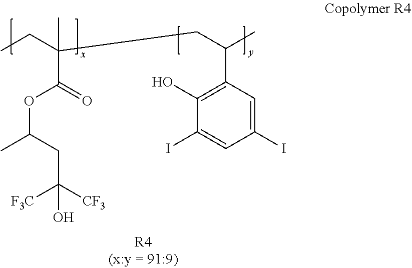

### Synthesis Example 6: Preparation of Copolymer R5

Copolymer R5 (Mw=5,000) was prepared in substantially the same manner as in Synthesis Example 2 except that a compound represented by Chemical Formula 3a (10.1 g, 36 mmol) (MA-TTBD, HALOCARBON) was used instead of the compound represented by Chemical Formula 1a.

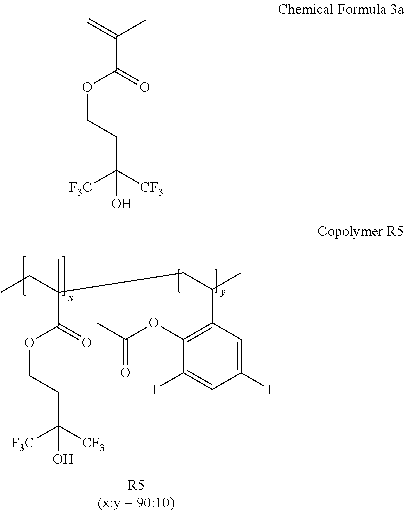

### Synthesis Example 7: Preparation of Copolymer R6

Copolymer R6 (Mw=5,000) was prepared in substantially the same manner as in Synthesis Example 2 except that a compound represented by Chemical Formula 3a (10.1 g, 36 mmol) instead of the compound represented by Chemical Formula 1a and a compound (1.5 g, 4 mmol) represented by Chemical Formula 2b (1.5 g, 4 mmol) instead of the compound represented by Chemical Formula 1b were used.

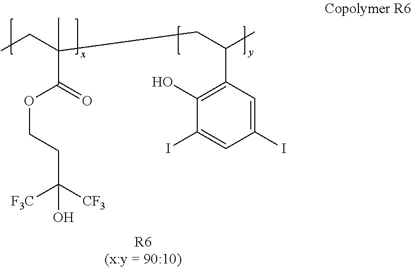

### Synthesis Example 8: Preparation of Copolymer R7

Copolymer R7 (Mw=5,000) was prepared in substantially the same manner as in Synthesis Example 2, except that the compound represented by Formula 1 b was not used.

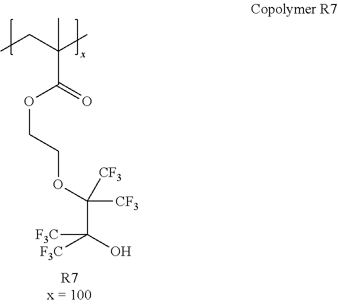

### Preparation of Resist Topcoat Compositions

### Example 1

0.98 g (0.5 wt %) of Copolymer R1 according to Synthesis Example 2 and 1.47 mg (0.15 wt %) of an amide-based matting agent represented by Q1 were dissolved in 199 g of a mixed solvent of DIAE/PGME (w/w=97/3) and then, stirred at room temperature (23° C.) for 24 hours and filtered through a TEFLON (tetrafluoroethylene) filter with a pore size of 0.45 micrometer (μm), preparing a resist topcoat composition.

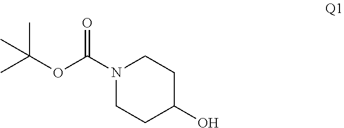

### Examples 2 to 18

Each resist topcoat composition was prepared in substantially the same manner as in Example 1 except that types (kinds) of the copolymer and types (kinds) of the amide-based matting agent were changed as shown in Table 1.

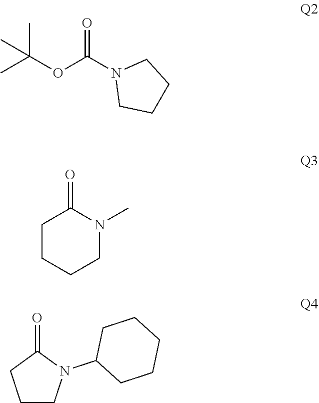

### Comparative Example 1

A resist topcoat composition was prepared in substantially the same manner as in Example 1 except that the amide-based matting agent was not used.

### Comparative Example 2

A resist topcoat composition was prepared in substantially the same manner as in Example 1 except that Copolymer R7 of Synthesis Example 8 was used instead of Copolymer R1.

### Evaluation 1: Solubility Evaluation

Each of the resist topcoat compositions according to Examples 1 to 10 and Comparative Example 1 was stirred for 24 hours and examined with respect to presence or absence of precipitates with naked eyes, and the results are shown in Table 1, wherein absence of precipitation—solubility is indicated by “◯”, and presence of precipitation—solubility is indicated by “X.”

### Evaluation 2: Developability Evaluation

Each of the resist topcoat compositions prepared in Examples and Comparative Examples was spin-coated on a silicon substrate and heat-treated at 110° C. on a hot plate for 1 minute, to form an about 5 nanometer (nm)-thick photoresist topcoat. The substrate with a topcoat formed thereon was rinsed with 2.38% tetramethylammonium hydroxide aqueous solution and heat-treated again at 110° C. on the hot plate for 1 minute and then, measured with respect to a thickness change of the topcoat layer, and the results are shown in Table 1.

* Residual film after development (%)=[Topcoat thickness before development (nm)−Topcoat thickness after development (nm)]×100/Topcoat thickness before development (nm)

(Residual film after development≤20%−Developability O, Topcoat thickness after development>20%−Developability X)

### Evaluation 3: Evaluation of Sensitivity and LWR

After forming a resist underlayer (thickness: 50 angstrom (A)) and a photoresist thin film for EUV (a thickness: 700 Å) on a 12-inch silicon substrate, each of the resist topcoat compositions according to the examples and the comparative examples was spin-coated and then, heat-treated at 110° C. for 1 minute on a hot plate to form about 5 nm-thick topcoats for photoresist.

A Line & Space pattern is formed in Focus-Energy Matrix (FEM) format on the wafer on which the topcoat for photoresist is formed using the NXE3400B EUV equipment. The optimal or suitable sensitivity capable of forming a Critical Dimension (CD) of 26.0 nm was confirmed using the interpolation method, and the results are shown in Table 1. After confirming the optimal or suitable sensitivity, the line width roughness (LWR) distribution was measured in the corresponding energy shot using Hitachi's CD-SEM equipment. In order to increase the reliability of the distribution value, the same pattern of 500 points was measured within the shot, and the final average value is shown in Table 1.

TABLE 1

| | Co- | Matting | Solu- | Develop- | Sensitivity | LWR |
|---|---|---|---|---|---|---|
| | polymer | agent | bility | ability | (mJ/cm²) | (nm) |
| Example 1 | R1 | Q1 | ∘ | ∘ | 44.7 | 1.85 |
| Example 2 | R2 | Q1 | ∘ | ∘ | 44.6 | 1.84 |
| Example 3 | R3 | Q1 | ∘ | ∘ | 44.6 | 1.82 |
| Example 4 | R4 | Q1 | ∘ | ∘ | 44.8 | 1.82 |
| Example 5 | R5 | Q1 | ∘ | ∘ | 44.7 | 1.83 |
| Example 6 | R6 | Q1 | ∘ | ∘ | 44.6 | 1.82 |
| Example 7 | R1 | Q2 | ∘ | ∘ | 45.0 | 1.89 |
| Example 8 | R2 | Q2 | ∘ | ∘ | 44.8 | 1.88 |
| Example 9 | R3 | Q2 | ∘ | ∘ | 44.9 | 1.87 |
| Example 10 | R4 | Q2 | ∘ | ∘ | 45.1 | 1.87 |
| Example 11 | R1 | Q3 | ∘ | ∘ | 44.6 | 1.98 |
| Example 12 | R2 | Q3 | ∘ | ∘ | 44.4 | 1.97 |
| Example 13 | R3 | Q3 | ∘ | ∘ | 44.5 | 1.95 |
| Example 14 | R4 | Q3 | ∘ | ∘ | 44.7 | 1.95 |
| Example 15 | R1 | Q4 | ∘ | ∘ | 44.7 | 1.93 |
| Example 16 | R2 | Q4 | ∘ | ∘ | 44.5 | 1.93 |
| Example 17 | R3 | Q4 | ∘ | ∘ | 44.6 | 1.91 |
| Example 18 | R4 | Q4 | ∘ | ∘ | 44.8 | 1.91 |
| Comparative | R1 | — | ∘ | ∘ | 45.2 | 2.08 |
| Example 1 | | | | | | |
| Comparative | R7 | Q1 | ∘ | ∘ | 50.3 | 2.10 |
| Example 2 | | | | | | |

Referring to Table 1, when the resist topcoat compositions according to examples of the present disclosure is applied, each of solubility, developability, and sensitivity enhance are improved, and pattern deterioration is suppressed or reduced, resulting in an excellent or suitable LWR improvement effect.

In contrast, in the case of the resist topcoat composition according to the comparative examples, the LWR improvement effect was not observed or the sensitivity was reduced.

The pattern manufacturing device, and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

In the context of the present application and unless otherwise defined, the terms “use,” “using,” and “used” may be considered synonymous with the terms “utilize,” “utilizing,” and “utilized,” respectively.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The certain preceding embodiments have been described and illustrated, however, it is apparent to a person with ordinary skill in the art that the present disclosure is not limited to one or more embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims, and equivalents thereof.

### REFERENCE NUMERALS

| | |
|---|---|
| 30: photoresist topcoat | 100: substrate |
| 101: photoresist layer | 102b: photoresist pattern |
| 1: forming a photoresist layer | 2: forming a photoresist |
| | topcoat |
| 3: exposing and developing the photoresist | |
| layer and the photoresist topcoat to form | |
| a resist pattern | |

What is claimed is:

1. A resist topcoat composition, comprising
a copolymer comprising a first structural unit represented by Chemical Formula M-1 and a second structural unit represented by Chemical Formula M-2;
an amide-based matting agent; and
a solvent, 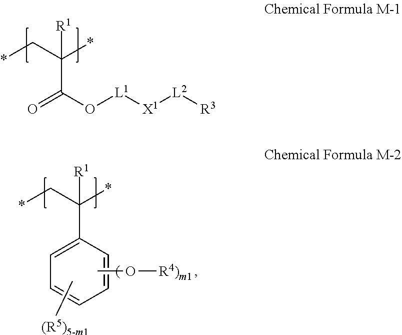
wherein, in Chemical Formula M-1 and Chemical Formula M-2,
R¹ and R² are each independently hydrogen or a substituted or unsubstituted C1 to C10 alkyl group,
L¹ and L² are each independently a single bond, a substituted or unsubstituted C1 to C10 alkylene group, or a combination thereof,
X¹ is a single bond, —O—, —S—, —S(O)—, —S(O)₂—, —C(O)—, —(CO)O—, —O(CO), —O(CO)O—, —NR^{a}— (R^{a} being hydrogen, deuterium, or a substituted or unsubstituted C1 to C10 alkyl group), or a combination thereof,
R³ is hydrogen, fluorine, a hydroxyl group, a substituted or unsubstituted C1 to C20 alkyl group, or a combination thereof,
R⁴ is hydrogen, or C(═O)R^{b},
R^{b} is a substituted or unsubstituted C1 to C10 alkyl group,
at least one selected from among R³, L¹, and L² comprises fluorine and a hydroxyl group,
R⁵ is hydrogen, a halogen, a hydroxy group, a substituted or unsubstituted C1 to C10 alkyl group, or a combination thereof,
m1 is an integer from 1 to 4, and
* is a linking point.

2. The resist topcoat composition as claimed in claim 1, wherein
the first structural unit is represented by Chemical Formula 1: 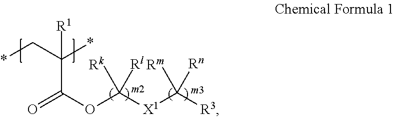
wherein, in Chemical Formula 1,
R¹ is hydrogen or a substituted or unsubstituted C1 to C10 alkyl group,
R^{k}, R^{l}, R^{m}, Rⁿ, and R³ are each independently hydrogen, fluorine, a hydroxy group, a substituted or unsubstituted C1 to C20 alkyl group, or a combination thereof,
m2 and m3 are each independently an integer from 1 to 10,
X¹ is a single bond, —O—, —S—, —S(O)—, —S(O)₂—, —C(O)—, —(CO)O—, —O(CO), —O(CO)O—, —NR^{a}— (R^{a} being hydrogen, deuterium, or a substituted or unsubstituted C1 to C10 alkyl group), or a combination thereof, and
at least one selected from among R^{k}, R^{l}, R^{m}, Rⁿ, and R³ comprises fluorine and a hydroxy group.

3. The resist topcoat composition as claimed in claim 1, wherein
the first structural unit is any one selected from among Group I: 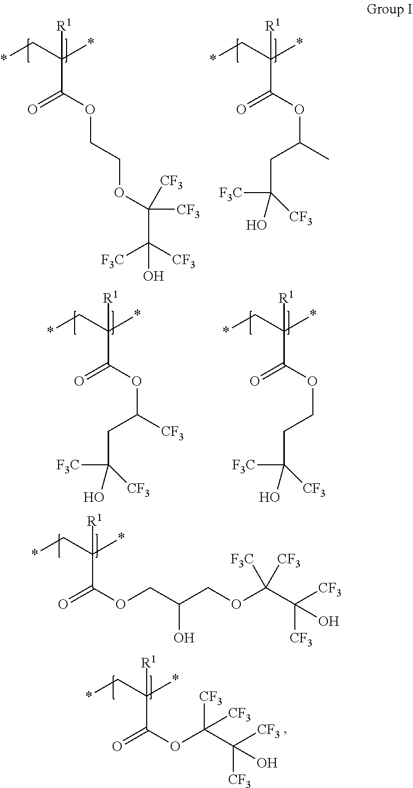
wherein, in Group I,
each R¹ is independently hydrogen or a methyl group, and * is a linking point.

4. The resist topcoat composition as claimed in claim 1, wherein
the second structural unit is represented by any one selected from among Chemical Formula 2-1 to Chemical Formula 2-4: 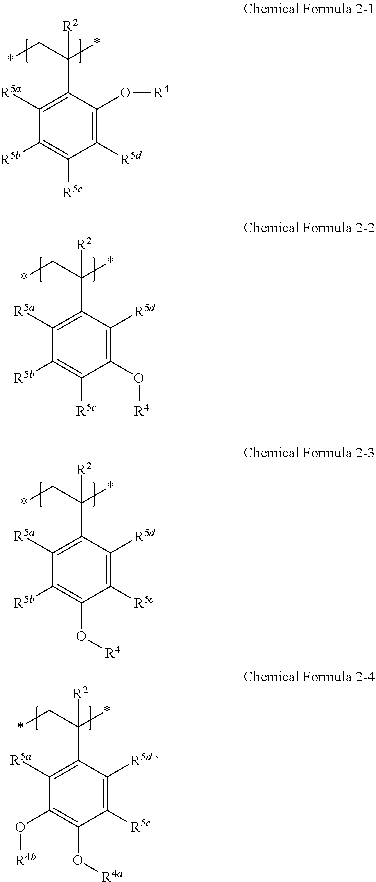
wherein, in Chemical Formula 2-1 to Chemical Formula 2-4,
R² is hydrogen or a methyl group,
R⁴, R^{4a}, and R^{4b} are each independently hydrogen, or C(═O)R^{b},
R^{b} is a substituted or unsubstituted C1 to C5 alkyl group,
R^{5a}, R^{5b}, R^{5c}, and R^{5d} are each independently hydrogen, a halogen, a hydroxy group, a substituted or unsubstituted C1 to C10 alkyl group, or a combination thereof, and
* is a linking point.

5. The resist topcoat composition as claimed in claim 4, wherein
at least one selected from among R^{5a}, R^{5b}, R^{5c}, and R^{5d} is an iodine group.

6. The resist topcoat composition as claimed in claim 1, wherein
the second structural unit is any one selected from among Group II: 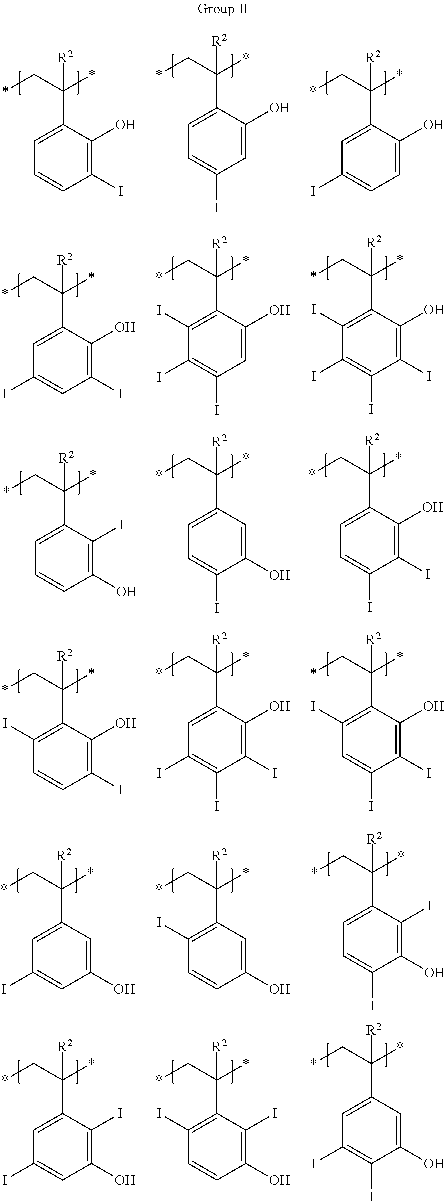 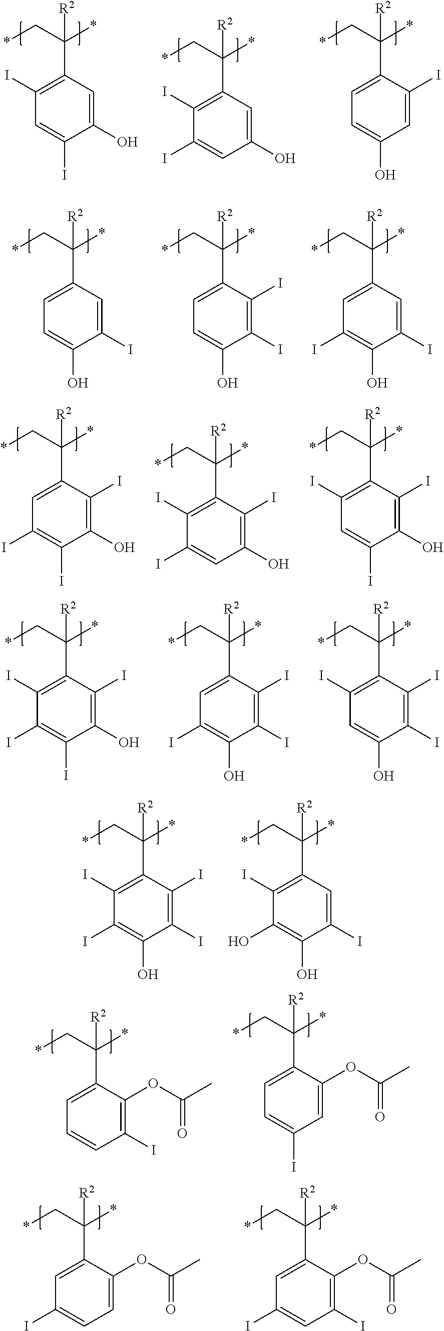 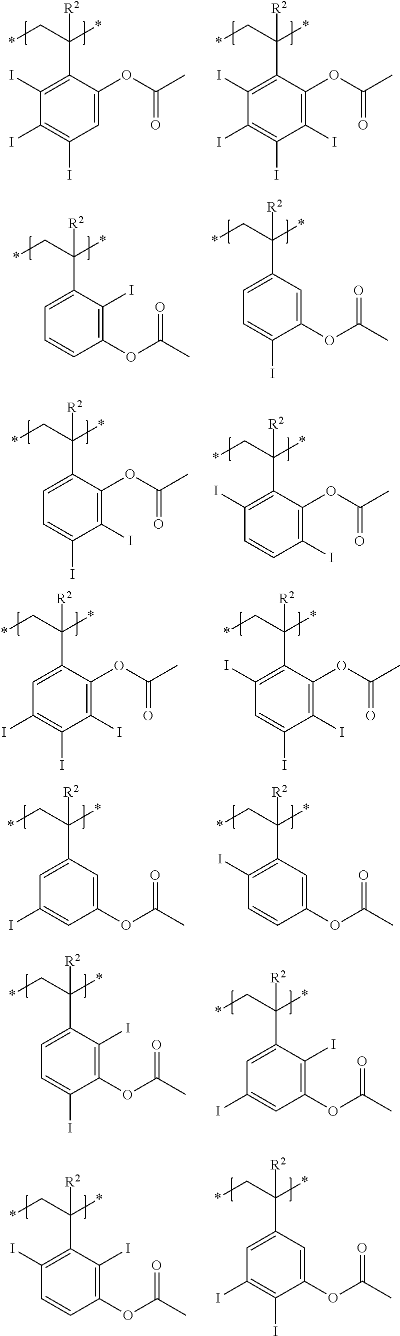 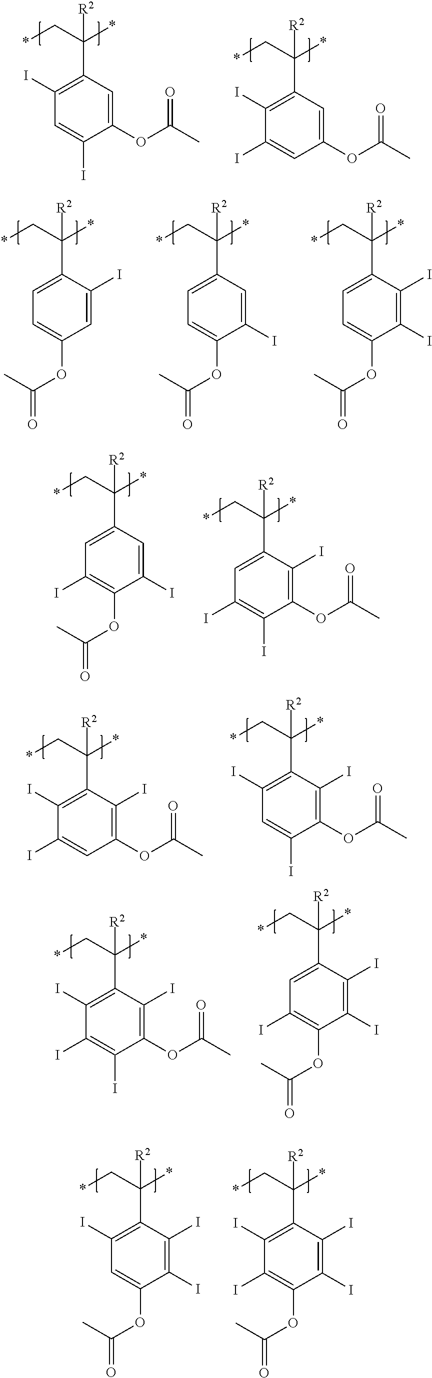 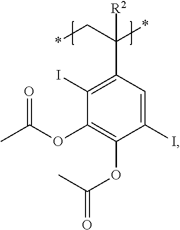
wherein, in Group II,
each R² is independently hydrogen or a methyl group, and * is a linking point.

7. The resist topcoat composition as claimed in claim 1, wherein
the copolymer comprises the first structural unit in an amount of about 50 to about 99 mol % and the second structural unit in an amount of about 1 to about 50 mol %.

8. The resist topcoat composition as claimed in claim 1, wherein
the copolymer has a weight average molecular weight of about 1,000 gram per mole (g/mol) to about 50,000 g/mol.

9. The resist topcoat composition as claimed in claim 1, wherein
the amide-based matting agent is a cyclic amine or a derivative thereof.

10. The resist topcoat composition as claimed in claim 1, wherein
the amide-based matting agent is any one selected from among compounds represented by Chemical Formula 3 and Chemical Formula 4: 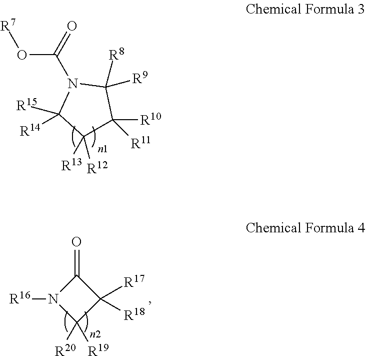
wherein, in Chemical Formula 3 and Chemical Formula 4,
R⁷ is a substituted or unsubstituted C1 to C20 alkyl group or a substituted or unsubstituted C3 to C20 cycloalkyl group,
R⁸ to R²⁰ are each independently hydrogen, a halogen, a hydroxy group, a substituted or unsubstituted C1 to C20 alkyl group, a substituted or unsubstituted C3 to C20 cycloalkyl group, a substituted or unsubstituted C1 to C20 alkoxy group, a substituted or unsubstituted C6 to C30 aryl group, or a combination thereof,
n1 is an integer from 1 to 3, and
n2 is an integer from 1 to 4.

11. The resist topcoat composition as claimed in claim 1, wherein
the amide-based matting agent is any one selected from among compounds listed in Group IV:

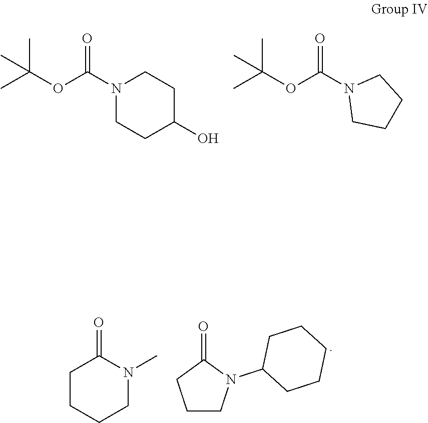

12. The resist topcoat composition as claimed in claim 1, wherein
the amide-based matting agent is in an amount of about 0.1 parts by weight to about 50 parts by weight based on 100 parts by weight of the copolymer.

13. The resist topcoat composition as claimed in claim 1, wherein
the solvent is an ether-based solvent.

14. A method of forming patterns, the method comprising:
coating and heating a photoresist composition on a substrate to form a photoresist layer;
coating and heating the resist topcoat composition as claimed in claim 1 on the photoresist layer to form a topcoat; and
exposing and developing the topcoat and the photoresist layer to form the patterns.

15. The method as claimed in claim 14, wherein exposing further comprises exposing to high-energy radiation comprising extreme ultraviolet radiation (EUV), electron beam radiation (E-Beam), or a combination thereof.

16. The method as claimed in claim 15, wherein the high-energy radiation comprises EUV having a wavelength of about 13.5 nanometer (nm).

17. The method as claimed in claim 14, wherein developing further comprises utilizing a developer, the developer comprising an alkaline developer, an organic-based developer, or a combination thereof.

18. The method as claimed in claim 17, wherein the alkaline developer comprises at least one selected from among quaternary ammonium salts, aqueous alkaline solutions, and combinations thereof.

19. The method as claimed in claim 17, wherein an amount of water of the developer is less than about 50 wt %.

20. The resist topcoat composition as claimed in claim 13, wherein the ether-based solvent is represented by Chemical Formula 5: 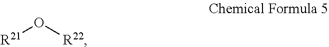
wherein R²¹ and R²² are each independently be a substituted or unsubstituted C3 to C20 alkyl group.
